(19) United States
(12) Patent Application Publication
(10) Pub. No.: US 2018/0337033 A1
(43) Pub. Date: Nov. 22, 2018

(54) NOVEL APPROACH TO IMPROVE SDB DEVICE PERFORMANCE

(71) Applicant: GLOBALFOUNDRIES Inc., Grand Cayman (KY)

(72) Inventors: Shesh Mani PANDEY, Saratoga Springs, NY (US); Srikanth Balaji SAMAVEDAM, Cohoes, NY (US); Jui-Hsuan FENG, Ballston Lake, NY (US)

(73) Assignee: GLOBALFOUNDRIES Inc., Grand Cayman (KY)

(21) Appl. No.: 15/596,437

(22) Filed: May 16, 2017

(51) Int. Cl. H01L 21/02

(52) U.S. Cl. CPC H01L 21/0243; H01L 21/02658; H01L 21/02019; H01L 21/02381; H01L 21/02518; H01L 21/02403

(57) ABSTRACT

Devices and methods of fabricating devices are provided. One method includes: patterning an isolation gate disposed above a trench, the trench extending into a substrate; patterning a gate structure disposed above the substrate and adjacent the isolation gate; depositing a set of sidewall spacers on either side of the isolation gate and gate structure; etching a set of cavities between the isolation gate and gate structure and extending into the substrate; and epitaxially growing a set of epitaxial growths in the set of cavities, wherein the isolation gate is wider than the gate structure, and wherein epitaxial growths adjacent the isolation gate substantially conform to an oxide layer between the isolation gate and the trench, contacting at least a portion of a bottom surface and at least a portion of a side surface of the oxide layer.

### FIELD OF THE INVENTION

The present invention relates to devices and methods of making devices with an improved epitaxial growth shape, and more particularly, to an intermediate semiconductor device wider isolation gate resulting in an epitaxial growth which contacts a bottom surface and a side surface of an oxide layer below the isolation gate.

### BACKGROUND

For logic devices, especially in integrated circuits, such as single diffusion break (SDB) devices, as the devices continue to shrink in size, the epitaxial growth formation can begin to lose its intended shape, resulting in increased current leakage. As the feature size reduces, the cavities formed and epitaxial growth grown therein begin to display a tapered shape, resulting in poor isolation and poor contact to any included contacts, impacting the drive current as well.

Therefore, it may be desirable to develop devices and methods of forming devices which allow for an improved epitaxial growth shape.

### BRIEF SUMMARY

The shortcomings of the prior art are overcome and additional advantages are provided through the provisions, in one aspect, a semiconductor structure that includes, for instance: at least one isolation gate disposed above a trench, the trench extending into a substrate; at least one gate structure disposed above the substrate and adjacent the at least one isolation gate; and a set of epitaxial growths between the at least one isolation gate and the at least one gate structure and extending into the substrate, wherein the at least one isolation gate is wider than the at least one gate structure, and wherein epitaxial growths adjacent the at least one isolation gate substantially conform to an oxide layer between the at least one isolation gate and the trench, contacting at least a portion of a bottom surface of the oxide layer and at least a portion of a side surface of the oxide layer.

In another aspect, a method of forming a semiconductor structure includes, for instance: patterning at least one isolation gate disposed above a trench, the trench extending into a substrate; patterning at least one gate structure disposed above the substrate and adjacent the at least one isolation gate; depositing a set of sidewall spacers on either side of the at least one isolation gate and the at least one gate structure; etching a set of cavities between the at least one isolation gate and the at least one gate structure and extending into the substrate; and epitaxially growing a set of epitaxial growths in the set of cavities, wherein the at least one isolation gate is wider than the at least one gate structure, and wherein epitaxial growths adjacent the at least one isolation gate substantially conform to an oxide layer between the at least one isolation gate and the trench, contacting at least a portion of a bottom surface of the oxide layer and at least a portion of a side surface of the oxide layer.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIGS. 1A-C depict a cross-sectional elevation view of an epitaxial growth and devices according to a previous embodiment;

FIGS. 2A and 2B depict a cross-sectional elevation view of devices according to a previous embodiment;

FIG. 2C depicts a cross-sectional elevation view of one embodiment of an intermediate semiconductor device having a wider isolation gate, in accordance with one or more aspects of the present invention;

FIG. 3 depicts a graph of performance of one embodiment of an intermediate semiconductor device having a wider isolation gate, in accordance with one or more aspects of the present invention;

FIG. 4 depicts a cross-sectional elevation view of one embodiment of an intermediate semiconductor device having a wider isolation gate and contacts, in accordance with one or more aspects of the present invention;

FIG. 5 depicts one embodiment of a method of forming an intermediate semiconductor device having a wider isolation gate, in accordance with one or more aspects of the present invention;

FIG. 6A depict a cross-sectional elevation view of an intermediate device with cavities according to a previous embodiment;

FIG. 6B depicts a cross-sectional elevation view of one embodiment of an intermediate semiconductor device having a wider isolation gate and formation of cavities, in accordance with one or more aspects of the present invention;

FIG. 7A depict a top down view of an intermediate device according to a previous embodiment; and

FIG. 7B depicts a top down view of one embodiment of an intermediate semiconductor device having a wider isolation gate and a plurality of fins, in accordance with one or more aspects of the present invention.

### DETAILED DESCRIPTION

Aspects of the present invention and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions and/or arrangements within the spirit and/or scope of the underlying inventive concepts will be apparent to those skilled in the art from this disclosure. Note also that reference is made below to the drawings, which are not drawn to scale for ease of understanding, wherein the same reference numbers used throughout different figures designate the same or similar components.

Generally stated, disclosed herein are intermediate semiconductor devices and methods of fabricating intermediate semiconductor devices. Advantageously, epitaxial growths adjacent an isolation gate are improved in shape, reducing current leakage and improving the drive current of the semiconductor devices.

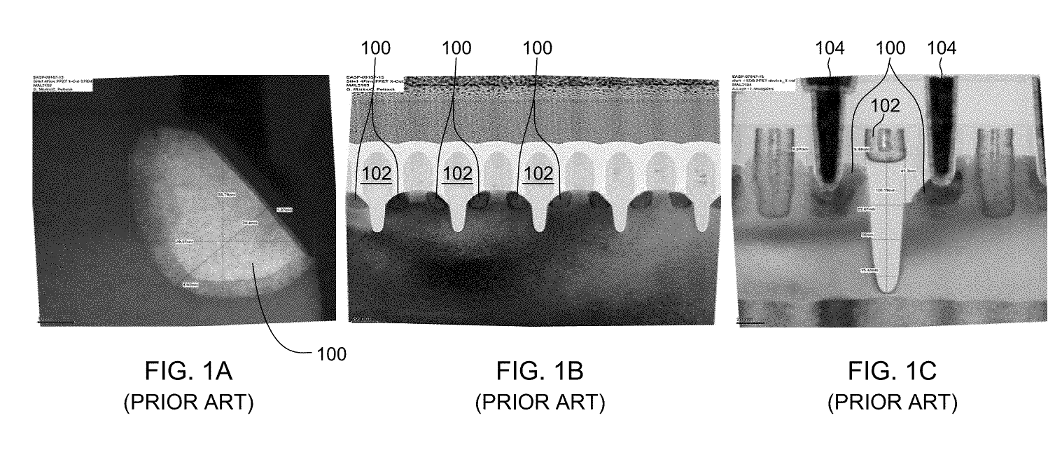

FIG. 1A shows an epitaxial growth 100 according to the state of the current art with a heavily tapered shape. As seen in FIG. 1B, the epitaxial growths 100 adjacent isolation gates 102 result in gaps from the tapered shape, resulting in poor isolation. FIG. 1C further illustrates the issues of the current art, wherein the contacts 104 fail to make a thorough contact to the epitaxial growths 100 surrounding an isolation gate 102, thus providing poor isolation and poor contact.

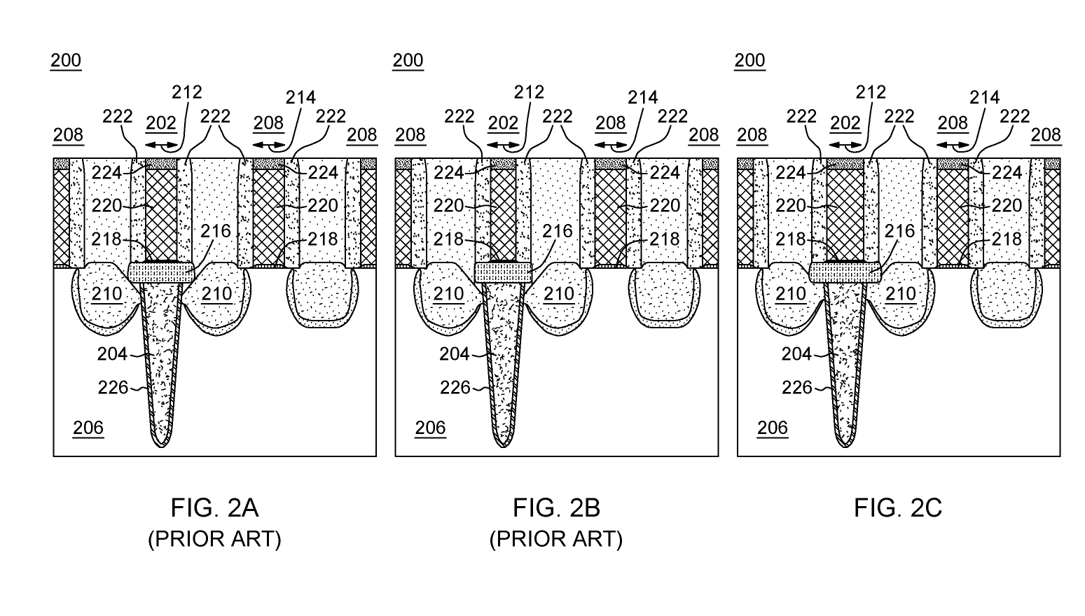

Turning to FIGS. 2A-2C, two prior art embodiments are illustrated next to one aspect of a semiconductor device 200 according to one embodiment of the current invention, for instance a logic device such as but not limited to a single diffusion break (SDB) device. When the semiconductor device 200 is a logic device, the logic device can include a NAND2 type, a NOR2 type, or an inverter type of logic device. For instance, at least one isolation gate 202 may be disposed above a trench 204, the trench 204 extending into a substrate 206, the substrate 206 can include silicon or any other substrate material.

In another embodiment (not shown), the substrate 206 of device 200 may include, for example, a silicon on insulator (SOI) substrate (not shown). For example, the SOI substrate may include an isolation layer (not shown), which may be a local buried oxide region (BOX) or any suitable material for electrically isolating transistors, aligned with the gate structure. In some embodiments, the device is a portion of a back end of line (BEOL) portion of an integrated circuit (IC).

Adjacent to the at least one isolation gate 202 may be disposed at least one gate structure 208 above the substrate 206. The at least one gate structure 208 can include the same materials used in the at least one isolation gate 202, but disposed directly above the substrate 206 and including active regions of semiconductor device 200, for instance logic gates of a logic device, including but not limited to NAND2 type, a NOR2 type, and/or an inverter type of logic gate.

Between the at least one isolation gate 202 and the at least one gate structure 208 may be a set of epitaxial growths 210 extending into the substrate 206. The epitaxial growths 210 can include SiGe, SiP, or similar materials epitaxially grown in cavities previously formed between the gates. The shape of epitaxial growths 210 is largely dependent upon the shape and size of the at least one isolation gate 202. For instance, in the current state of technology, a width 212 of the isolation gate 202 will be the same as a width 214 of the at least one gate structure 208. The width 214 of the at last one gate structure 208 is determined by the size of the device. Thus, as illustrated in FIG. 2A, when width 212 and width 214 are equal, the set of epitaxial growths 210 are tapered and make poor contact with an oxide layer 216 disposed between the at least one isolation gate 202 and the trench 204, the oxide layer 216 typically being approximately as wide as the at least one isolation gate 202. This results in poor isolation and increased leakage current of the device 200. Turning to FIG. 2B, if the width 212 of the isolation gate 202 is reduced relative to the width 214 of the at least one gate structure 208, the taper of the epitaxial growths 210 becomes more dramatic, increasing the gaps and decreasing contact with the oxide layer 216. However, according to embodiments of the current invention, turning to FIG. 2C, if the width 212 of the isolation gate 202 is increased relative to the width 214 of the gate structures 208, the taper can be reduced or eliminated, resulting in little to no gap between the epitaxial growths 210 and the oxide layer 216, causing a conformal or near conformal structure which contacts at least a portion of a bottom surface of the oxide layer 216 and at least a portion of a side surface of the oxide layer 216.

In some embodiments, the width 214 of the gate structure may be 20 nanometers (nm), as depicted in FIGS. 2A-2C. However, this is only illustrative, as width 214 may be less than 20 nm, for instance 17 nm or 14 nm. The width 212 of the isolation gate may be 2-3 nm wider than width 214 in some embodiments. In another embodiment, the width 212 may be 2-3 nm wider than width 214 on each side of the isolation gate 202, for a total of 4-6 nm wider than the gate structures 208. The width 212 of the isolation gate 202 determines the cavity shape when etched, and thus the shape of the epitaxial growth 210. Widening the isolation gate 202 relative to the gate structures 208 can improve the shape of epitaxial growths 210 without affecting other device performance, other than improving the drive current and leakage current.

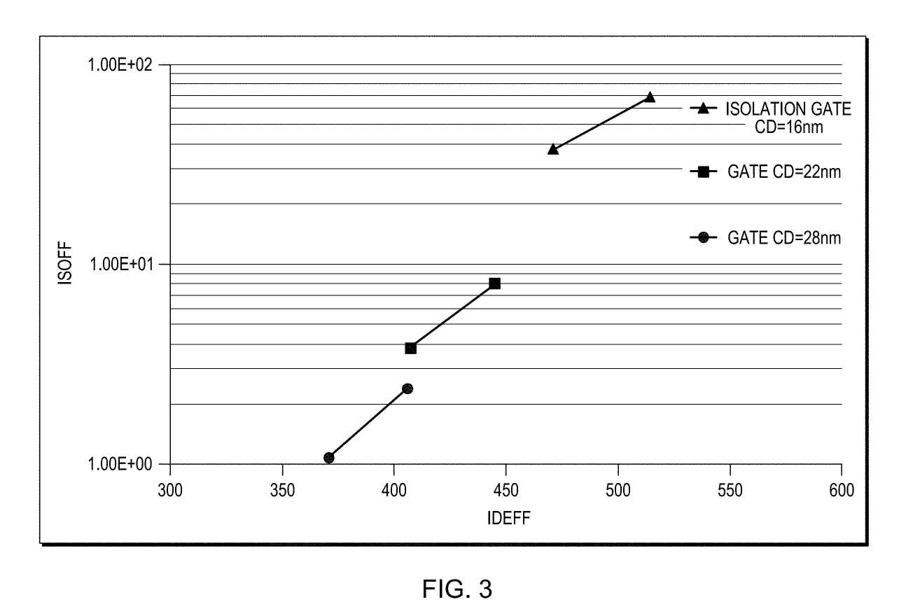

As seen in FIG. 3, the increased performance of a device 200 according to some embodiments of the current invention can be illustrated with a graph of the x-axis showing drive current and the y-axis showing leakage current. The numbers on the graph are arbitrary units for illustration purposes only, and are not intended to be limiting in any way. With a width 212 of the isolation gate 202 varying for a width 114 of gate structure 208 being 20 nm, the 16 nm width has very poor performance, and the 20 nm width has poor performance. However, by widening the isolation gate 202 to 28 nm, the performance sees a significant increase, with the leakage current dropping significantly relative to the drive current. Although a 28 nm isolation gate is used for the results, the isolation gate could be from 21 nm to 30 nm wide, rather than 28 nm. While results are shown for a 20 nm gate structure, similar results are obtained for a gate structure of smaller sizes, for instance 17 nm and 14 nm. In these embodiments, the isolation gate could be between 1 nm wider than the gate structure up to 8 nm wider than the gate structure.

Returning to FIGS. 2A-2C, the at least one isolation gate 202 and at least one gate structure 208 can include commonly known gate stacks. For instance, the isolation gate 202 can include a high-k layer 218 above the oxide layer 216, while the gate structure 208 can include the high-k layer 218 directly above the substrate 206. Disposed above high-k layer 218 can be a polysilicon layer 220 extending vertically, frequently referred to as the gate material. Extending conformally along either side of the polysilicon material 220 can be a set of sidewall spacers 222. A capping material 224 may be included above the polysilicon layer 220.

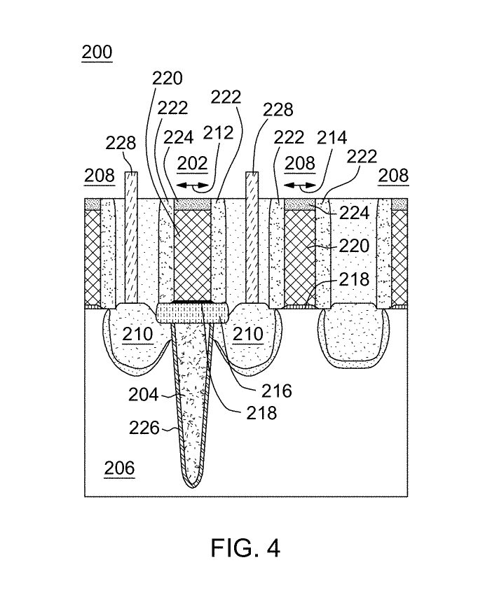

In some embodiments, the trench 204 may be an oxide material, and may further include an oxide liner 226 of higher purity oxide material. The trench 204 may be part of a shallow trench isolation (STI) trench, which combined with the at least one isolation gate 202 above, forms an STI gate. In these embodiments, a set of contacts 228, as illustrated in FIG. 4, on either side of the at least one isolation gate 202, extending from above the isolation gate 202 into the epitaxial growths 210 adjacent to the isolation gate 202, forming an STI with source and drain contacts which benefits from the improved performance abilities of the epitaxial growths 210, and forming a better connection than the poorly connected contacts of the prior art, and as illustrated in FIG. 1C.

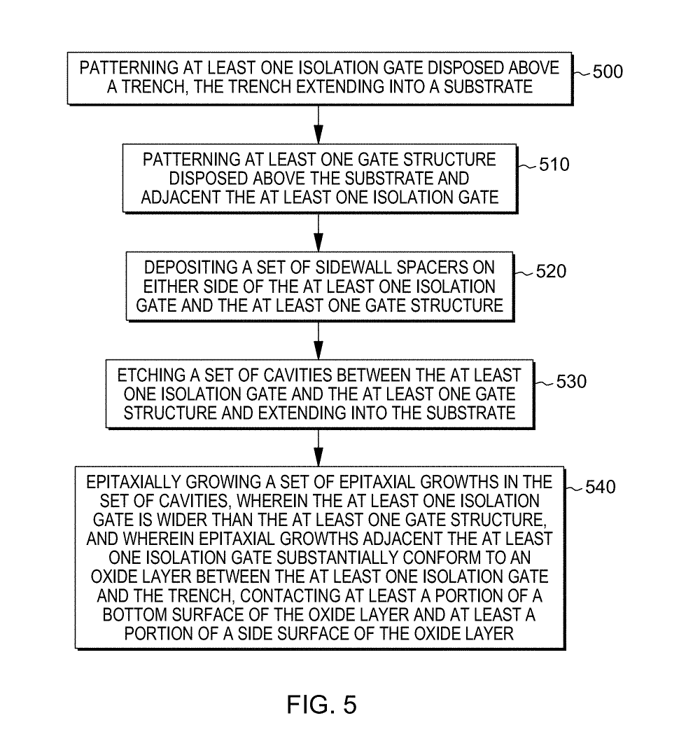

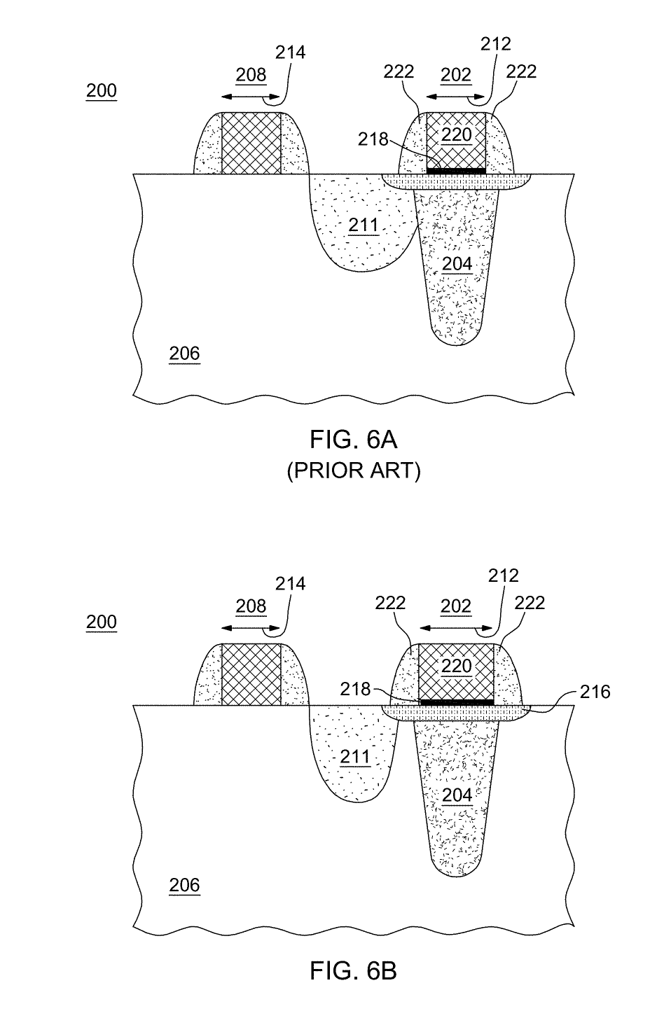

In one aspect, in one embodiment, as shown in FIG. 5, a method of making a semiconductor structure according to the above embodiments may include patterning at least one isolation gate (202; FIG. 2C) disposed above a trench (20204; FIG. 2C), the trench extending into a substrate (206; FIG. 2C) 500. At 510 at least one gate structure (208; FIG. 2C) may be patterned above the substrate (206; FIG. 2C) and adjacent the at least one isolation gate (202; FIG. 2C). The isolation gate and the gate structure may be patterned or defined using known techniques, including but not limited to etching techniques. At 520, a set of sidewall spacers (222; FIG. 2C) may be deposited on either side of the isolation gate(s) and the gate structure(s) using known deposition techniques. At 530, a set of cavities (211; FIG. 6B) may be etched between the at least one isolation gate (202; FIG. 2C) and the at least one gate structure (208; FIG. 2C). Turning to FIGS. 6A and 6B, the prior art methods shown in FIG. 6A demonstrate the flawed shape of cavities 211 when the gates are of the same width. In FIG. 6B, using methods according to the disclosed embodiments, the increased width 212 of the isolation gate 202 illustrates a better shaped cavity 211, resulting in better epitaxial growth within the cavity 211.

Returning to FIG. 5, at 540, a set of epitaxial growths (210; FIG. 2C) are grown in the cavities (211; FIG. 6B) using known methods, including epitaxy and doping techniques where necessary. Seed atoms may be deposited before epitaxial growth. Methods can further include forming a set of contacts (228; FIG. 4) on either side of the at least one isolation gate (202; FIG. 4), which may extend from above the isolation gate and into the epitaxial growths (210; FIG. 4).

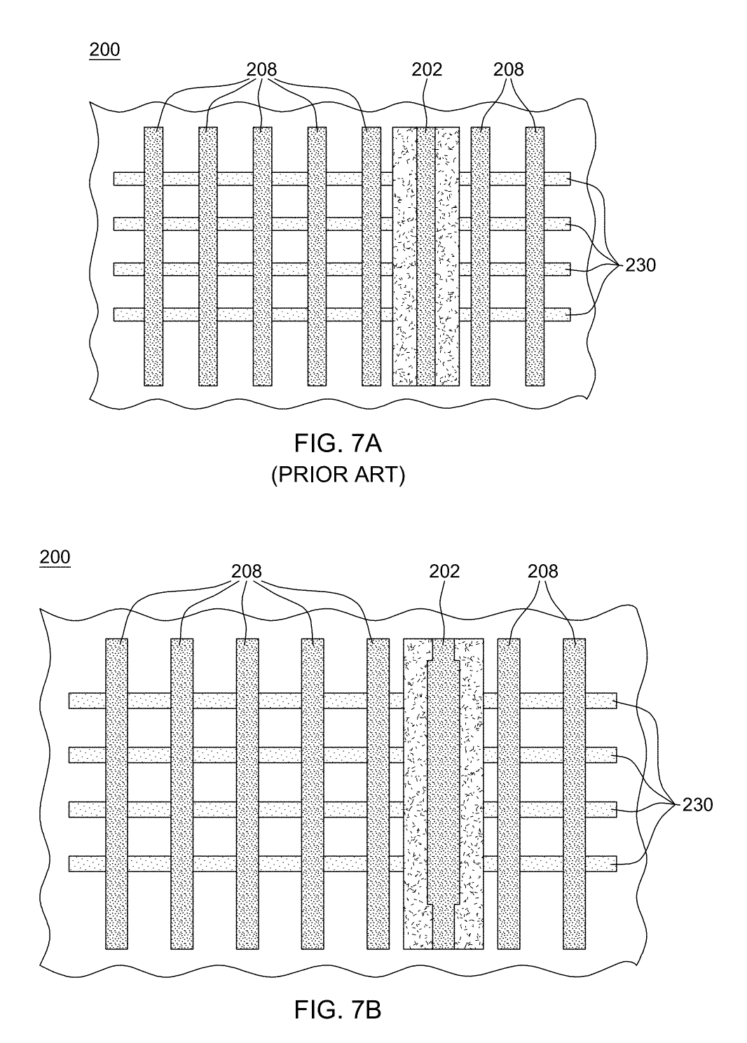

FIGS. 7A and 7B illustrate a top down view of a device 200. In FIG. 7A, a device of previous methods is shown with all gates being the same width. As seen in FIG. 7B, according to some embodiments, the isolation gate 202 is wider than the gate structures 208. As shown, the device 200, according to certain embodiments, may further include a plurality of fins 230 may run substantially perpendicular to the isolation gate(s) 202 and the gate structure(s) 208. The plurality of fins 230 may run under, or through, the isolation gate(s) 202 and the gate structure(s) 208 as part of the device 200, forming for instance, a logic device.

Thus, using embodiments described above, by increasing the width of isolation gates in semiconductor devices, epitaxial growths can be formed with better shape, fewer gaps, and a less tapered structure, causing better connection to the surrounding features. This allows for smaller features to be fabricated, while improving the device performance, particularly the leakage current relative to the drive current.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

1. A semiconductor structure comprising:
at least one isolation gate disposed above a trench, the trench extending into a substrate;
at least one gate structure disposed above the substrate and adjacent the at least one isolation gate; and
a set of epitaxial growths between the at least one isolation gate and the at least one gate structure and extending into the substrate, wherein the at least one isolation gate is wider than the at least one gate structure, and wherein epitaxial growths adjacent the at least one isolation gate substantially conform, in shape, to an oxide layer between the at least one isolation gate and the trench, contacting an entirety of an exposed portion of a bottom surface of the oxide layer and at least a portion of a side surface of the oxide layer.

2. The semiconductor structure of claim 1, wherein the isolation gate comprises a shallow trench isolation gate.

3. The semiconductor structure of claim 2, wherein the semiconductor structure further comprises:
a set of contacts on either side of the at least one isolation gate extending from above the at least one isolation gate and into the epitaxial growths adjacent the at least one isolation gate.

4. The semiconductor structure of claim 1, wherein the at least one isolation gate is between 2 and 3 nanometers wider than the at least one gate structure.

5. The semiconductor structure of claim 4, wherein the at least one isolation gate is between 2 and 3 nanometers wider than the at least one gate structure on each side of the at least one isolation gate.

6. The semiconductor structure of claim 1, wherein the at least one gate structure is approximately 20 nanometers wide.

7. The semiconductor structure of claim 1, wherein a leakage current of the semiconductor structure is reduced relative to a drive current of the semiconductor structure.

8. The semiconductor structure of claim 1, wherein the semiconductor structure comprises a logic device.

9. The semiconductor structure of claim 8, wherein the logic device is a NAND2 type, a NOR2 type, or an inverter type.

10. The semiconductor structure of claim 1, wherein the at least one isolation gate includes a high-k layer above the oxide layer, a vertically extending polysilicon material above the high-k layer, and a set of sidewall spacers conformally extending along either side of the polysilicon material, and wherein the at least one gate structure includes a second high-k layer above the substrate, a second vertically extending polysilicon material above the second high-k layer, and a second set of sidewall spacers conformally extending along either side of the polysilicon material.

11. A method of making a semiconductor structure comprising:
patterning at least one isolation gate disposed above a trench, the trench extending into a substrate;
patterning at least one gate structure disposed above the substrate and adjacent the at least one isolation gate;
depositing a set of sidewall spacers on either side of the at least one isolation gate and the at least one gate structure;
etching a set of cavities between the at least one isolation gate and the at least one gate structure and extending into the substrate; and
epitaxially growing a set of epitaxial growths in the set of cavities, wherein the at least one isolation gate is wider than the at least one gate structure, and wherein epitaxial growths adjacent the at least one isolation gate substantially conform, in shape, to an oxide layer between the at least one isolation gate and the trench, contacting an entirety of an exposed portion of a bottom surface of the oxide layer and at least a portion of a side surface of the oxide layer.

12. The method of claim 11, wherein the isolation gate comprises a shallow trench isolation gate.

13. The method of claim 12, wherein the method further comprises:
forming a set of contacts on either side of the at least one isolation gate extending from above the at least one isolation gate and into the epitaxial growths adjacent the at least one isolation gate.

14. The method of claim 11, wherein the at least one isolation gate is between 2 and 3 nanometers wider than the at least one gate structure.

15. The method of claim 14, wherein the at least one isolation gate is between 2 and 3 nanometers wider than the at least one gate structure on each side of the at least one isolation gate.

16. The method of claim 11, wherein the at least one gate structure is approximately 20 nanometers wide.

17. The method of claim 11, wherein a leakage current of the semiconductor structure is reduced relative to a drive current of the semiconductor structure.

18. The method of claim 11, wherein the semiconductor structure comprises a logic device.

19. The method of claim 18, wherein the logic device is a NAND2 type, a NOR2 type, or an inverter type.

20. The method of claim 11, wherein the at least one isolation gate includes a high-k layer above the oxide layer, a vertically extending polysilicon material above the high-k layer, and a set of sidewall spacers conformally extending along either side of the polysilicon material, and wherein the at least one gate structure includes a second high-k layer above the substrate, a second vertically extending polysilicon material above the second high-k layer, and a second set of sidewall spacers conformally extending along either side of the polysilicon material.
